(19) United States
(12) Patent Application Publication
(10) Pub. No.: US 2013/0037618 A1
(43) Pub. Date: Feb. 14, 2013

(54) METHOD AND SYSTEM FOR PRODUCING ANTENNAS

(71) Applicant: Angelo Pagani, Bologna (IT)

(72) Inventor: Angelo Pagani, Bologna (IT)

(73) Assignee: GALILEO VACUUM SYSTEMS S.P.A. IN LIQUIDAZIONE, Prato (IT)

(21) Appl. No.: 13/639,946

(22) PCT Filed: May 4, 2011
(86) PCT No.: PCT/IT11/00138

§ 371 Date: Oct. 8, 2012

(30) Foreign Application Priority Data
May 7, 2010 (IT) FI2010A000095

(51) Int. Cl. H01Q 1/36; C23C 16/54; G06K 19/077; B05D 5/12

(52) U.S. Cl. 235/492; 427/58; 427/534; 118/718; 118/712; 343/700 MS

(57) ABSTRACT

A method for producing RFID antennas by vacuum deposition of an electrically conductive material on a web material, wherein at least a first and a second deposition of electrically conductive material are carried out in subsequent steps according to a pattern corresponding to the shape of the antennas.

### TECHNICAL FIELD

The present invention relates to RFID (Radio Frequency Identification) technology. In particular the present invention relates to improvements to the technology for producing RFID antennas.

### STATE OF THE ART

For producing electronic tags, identification devices, customized badges for access to various types of services and for other applications, circuits based on RFID technology are used with increasing frequency. Electronic tags or RFID tags are gradually replacing other identification systems, such as bar codes, due to the greater intrinsic safety of RFID systems.

RFID tags are of various types and are classified according to the frequencies utilized for their use. More in particular, the current ISO standards provide for operating frequencies of 125/134 kHz, 13.56 MHz, 868/915 MHz, or frequencies above 2.4 GHz. RFID devices can be of the active, semi-passive or passive type. Active systems are powered by a battery, semi-passive systems are powered by a battery only to maintain the internal circuit active, while for radiation they use part of the energy received from the radio waves that transmit the information; passive systems have no internal power source but draw energy from the radio waves transferred from the reader that interrogates the RFID device.

RFID devices have antennas of very large dimensions with respect to the control circuit. These antennas are usually produced on a plastic film or other sheet support. One of the techniques currently used is that of carrying out vacuum deposition of a sufficiently thick layer of metal or other electrically conductive material on a film. The film is subsequently processed to produce the antennas by means of chemical etching, with which the metal is eliminated in the areas not to be coated with metal, generating a circuit formed by the residual portions of the metallization layer remaining after the chemical etching process.

### SUMMARY OF THE INVENTION

The present invention provides for a new method for manufacturing antennas for RFID circuits, which makes it possible to overcome some problems and limits of conventional techniques. In substance, the method according to the invention provides for carrying out, in subsequent steps, at least a first and a second deposition of conductive material according to a pattern corresponding to the shape of the RFID antennas.

With a process of this type antennas for RFID devices can be obtained without requiring chemical etching, a technique that involves lengthy production times and problems of environmental pollution caused by the use of particularly toxic and aggressive chemical substances.

Further advantageous features and embodiments of the method according to the invention are described hereunder and are defined in the dependent claims, which form an integral part of the present description.

In some possible embodiments, the method according to the invention comprises the steps of:
a. feeding the web material around a process roller;
b. depositing the electrically conductive material on said web material according to the pattern corresponding to the RFID antennas to be produced;
c. repeating steps (a) and (b) by a number of times sufficient to reach a preset thickness of the electrically conductive material forming the RFID antennas.

According to other embodiments, the method of the present invention comprises the steps of:
feeding the web material in sequence around at least a first and a second process roller arranged in series along a feed path;
depositing a first amount of electrically conductive material on said web material according to the pattern corresponding to the RFID antennas to be produced with a first vaporization source associated with the first process roller;
depositing a second amount of electrically conductive material on said web material according to the pattern corresponding to the RFID antennas to be produced with a second vaporization source associated with the second process roller.

It would be possible, for example, to provide for further amounts of electrically conductive material to be deposited on the web material according to the pattern corresponding to the RFID antennas to be produced with further vaporization sources associated with further process rollers arranged in series along the feed path of a multi-chamber system.

According to other embodiments of the invention, the method comprises the steps of:
a. arranging a reel of web material to be processed in a metallization system comprising at least: an unwinder, a process roller, a vaporization source associated with said process roller, and a winder;
b. unwinding said reel of web material to be processed by means of said unwinder;
c. feeding the web material, unwound from said reel of web material to be processed, along a feed path and around the process roller;
d. depositing a first amount of electrically conductive material on the web material according to the pattern corresponding to the RFID antennas to be produced through said vaporization source;
e. rewinding the web material on a winding reel;
f. at the end of processing of the reel of web material to be processed, arranging the winding reel on the unwinder and repeating the steps (b) to (e) one or more times depositing, according to the same pattern and in phase therewith, further amounts of electrically conductive material.

To carry out deposition of the electrically conductive material according to a pattern corresponding to the shape of the RFID antennas to be produced, a liquid can be applied to the web material, according to a pattern complementary to the pattern of the RFID antennas to be produced, which prevents anchoring of the electrically conductive material on the web material so that the electrically conductive material dispensed by the vaporization source anchors on the web material only on the surfaces corresponding to the RFID antennas to be produced. Application is repeated before each deposition of electrically conductive material. Application takes place so that at each application subsequent to the first, the liquid is applied according to the complementary pattern in phase with the pattern of the electrically conductive material applied in the previous deposition step.

Advantageously, the web material can be fed continuously through the station or stations for the deposition of the electrically conductive material, thus obtaining high productivity. The speed can advantageously be between 50 m/min and 1000 m/min.

According to a different aspect, the invention relates to a system for vacuum deposition of a conductive material on a web material, for producing RFID antennas, comprising: at least one vacuum chamber; at least one unwinder for a reel of web material; at least one winder for winding the processed web material; preferably, at least one process roller along a feed path of the web material from the unwinder to the winder; at least one vaporization source associated with said process roller; at least one applicator of a liquid on the web material upstream of said vaporization source, for preventing anchoring of the electrically conductive material at a pattern complementary to a pattern of the RFID antennas to be produced; a system for phasing the applicator with respect to the web material.

In some embodiments of the system according to the invention the applicator phasing system comprises: at least one detector for detecting a reference on the web material; longitudinal web material phasing members and cross web material phasing members controlled by signals from said detector, so as to superimpose the electrically conductive material always according to the same pattern at each deposition passage so as to form a coating obtained by superimposing several layers deposited in subsequent passages with a longitudinal and cross phasing.

The system can be of the multi-chamber or single chamber type, for example of the roll-to-roll type.

Further advantageous features of the method and of the system according to the invention are indicated in the dependent claims, which form an integral part of the present description.

According to a further aspect, the invention relates to a web material comprising a plurality of coatings of vacuum-deposited electrically conductive material defining RFID antennas, each coating formed by several superposed layers deposited in sequence, each deposited in a vacuum.

According to yet another aspect, the invention relates to an RFID antenna comprising a sheet support, i.e. a material in web or sheet form, whereon there is provided a coating of electrically conductive material consisting of several superposed layers deposited in sequence by vacuum vaporization.

According to a further aspect, the invention also relates to an electronic device comprising a sheet support, i.e. a portion of material in web or sheet form, whereon there is applied at least one integrated circuit in electrical connection with an RFID antenna consisting of at least one coating of electrically conductive material consisting of several superposed layers deposited in sequence by vacuum vaporization.

### BRIEF DESCRIPTION OF THE DRAWINGS

The invention will be better understood by following the description and the accompanying drawing, wherein:

FIG. 1 shows a schematic side view of a system according to the invention in a first embodiment;

FIG. 2A shows a schematic representation, in a first embodiment, of the main members for controlling processing of the web material forming the substrate on which the vacuum depositions are carried out;

FIG. 2B shows a schematic representation, in a second embodiment, of the main members for controlling processing of the web material forming the substrate on which the vacuum depositions are carried out;

FIG. 3 shows a diagram of a multi-chamber system for carrying out the method according to the invention;

FIG. 4 shows a portion of plastic film with a plurality of RFID antennas produced thereon by vacuum deposition;

FIG. 5 shows an enlarged schematic local section, not to scale, according to V-V of FIG. 4; and

FIG. 6 shows an RFID device with an antenna and an integrated circuit electrically connected thereto.

### DETAILED DESCRIPTION OF EMBODIMENTS OF THE INVENTION

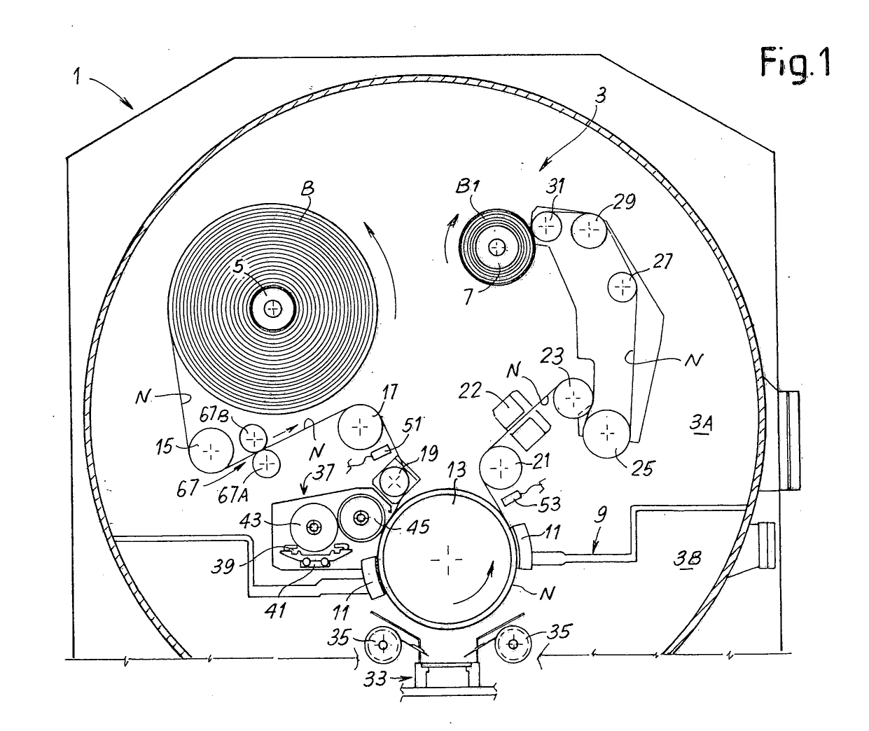

With initial reference to FIG. 1, a first embodiment provides for a vacuum metallization system, indicated as a whole with the numeral 1 and represented in a schematic side view with the chamber open.

The system 1 comprises a vacuum chamber 3 inside which an unwinder 5 for a reel of web material B to be processed, for example a plastic film, and a winder 7 for winding of a reel B1 of processed material are arranged. The winder 7 and the unwinder 5 are located in a portion 3A of the chamber 3, in which there is generated, in a known manner, a lesser degree of vacuum than that generated in a second portion of chamber, indicated with 3B, in which the metal material is actually deposited on the web material unwound from the reel B. Separation of the two portions 3A and 3B of the vacuum chamber is obtained by a partition baffle indicated as a whole with 9, comprising guard chambers 11 arranged adjacent to a process roller 13, around which the web material N unwound from the reel B is fed to receive the metal material vaporized in the portion of chamber 3B.

The path of the web material N unwound from the reel B and rewound on the reel B1 is defined by a series of further rollers arranged upstream and downstream of the process roller 13, More in particular, along the path of the web material N there are arranged: a first idle roller 15, a second idle roller 17, a spreader roller 19, an idle roller 21 with load cell, a further idle roller 23, a capstan roller 25, a spreader roller 27, a fifth idle roller 29 and a so-called dancer roller 31.

The position of the rollers described above is known and can be modified according to system requirements, to the type of machine utilized, to the type of material forming the web material N and to the metal or other electrically conductive material that is deposited by vaporization on the web material N.

Underneath the process roller 13 vaporization sources are arranged, indicated as a whole with 33, for example of the Joule effect type, fed with coils of metal material 35. The sources can be designed, for example, as described in WO-A-2007/05792.

Associated with the process roller 13 is a printing unit 37. This latter can comprise, for example, a source of a liquid material 39 provided with heating elements 41, for example an electrical resistor. The latter heats the liquid contained in the tank 39 and makes it evaporate. The vapor obtained subsequently condenses on an anilox roller 43 of the printing unit 37. The anilox roller 43 transfers the condensed liquid material to a printing roller 45 which forms, with the process roller 13, a printing nip through which the web material unwound from the reel B and fed to the process roller 13 passes. The printing unit 37 can be designed, for example, as described in WO-A-2008/116617, the content of which is fully incorporated in the present description.

On the printing roller 45 there are provided raised elements, i.e. projections the shape of which corresponds to the area of the film or web material N that is not to be metalized. In substance, the printing roller 45 applies a liquid, for example an oil, which prevents the electrically conductive material vaporized by the source 33 from anchoring on the web material N in the areas outside the profile of the RFID antennas to be produced. The hollow areas of the printing roller 45 correspond to the areas to be metalized, i.e. have the shape of the antennas to be obtained by deposition of the electrically conductive material on the web material N.

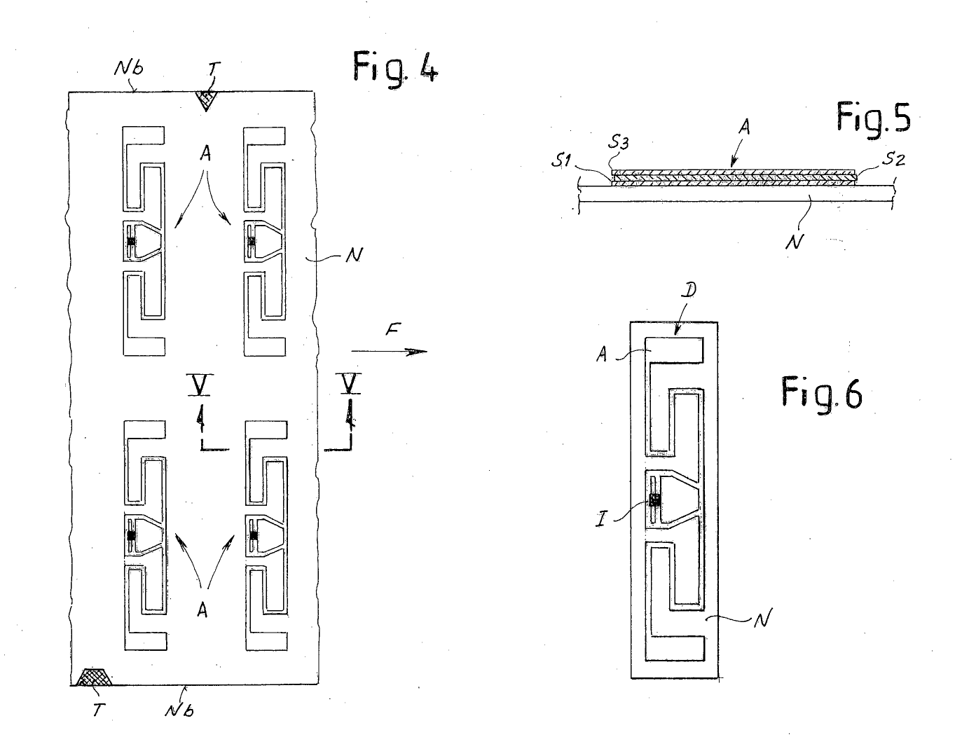

FIG. 4 shows a portion of web material N on which four antennas for RFID devices are shown, indicated as a whole with A and manufactured by vacuum deposition of a metal coating on the web material N. The printing roller 45 with which these antennas are produced therefore has, on the surface thereof, a hollow area corresponding to the metalized area of the web material N and applies the liquid to the whole of the surrounding surface preventing anchoring of the electrically conductive material which, vaporized by the source 33, condenses on the web material N.

Characteristically, according to the invention, to obtain a sufficiently thick coating of conductive material to produce an RFID antenna, multiple vacuum deposition operations are carried out in sequence on the same plastic film or other web material N, depositing at each deposition passage a layer of electrically conductive material of a thickness which is less than the total thickness of the desired coating to be obtained, i.e. to the total thickness of the antenna A. At each deposition passage the electrically conductive material is applied according to the pattern defined by the printing roller, superimposing the deposition areas at each passage.

To carry out vacuum deposition of subsequent layers to form the total coating that forms the antenna A, it is necessary that in each step of the process a correct phasing between the web material N and the printing roller 45 or, more precisely, between the electrically conductive material deposited in the previous step and the pattern on the printing roller 45 is maintained.

For this purpose, the web material N can advantageously be provided with reference marks or photocell marks T, along the edges Nb of the web material N (FIG. 4). Advantageously, the reference marks T can have a trapezoidal or triangular shape with inclined edges, i.e. edges which are not orthogonal to the corresponding edge Nb parallel to the direction of feed F of the web material N along the machine 1. In the schematic example shown in FIG. 4, the reference marks T provided are triangular or trapezoidal in shape, it being understood that the shape of these marks is not binding.

Inside the machine 1 there are advantageously provided both longitudinal and cross phasing systems of the web material N, so that the pattern produced by the printing roller 45 at each subsequent passage of the web material N is in phase with the pattern produced in the previous passage.

In the example shown in FIG. 1 along the path of the web material N from the unwinder 5 to the winder 7 there are provided two optoelectronic control devices 51 and 53 which detect the position of the reference marks T on the web material N to correct the cross and/or longitudinal position of the web material with respect to the position identified by the devices 51 and 53.

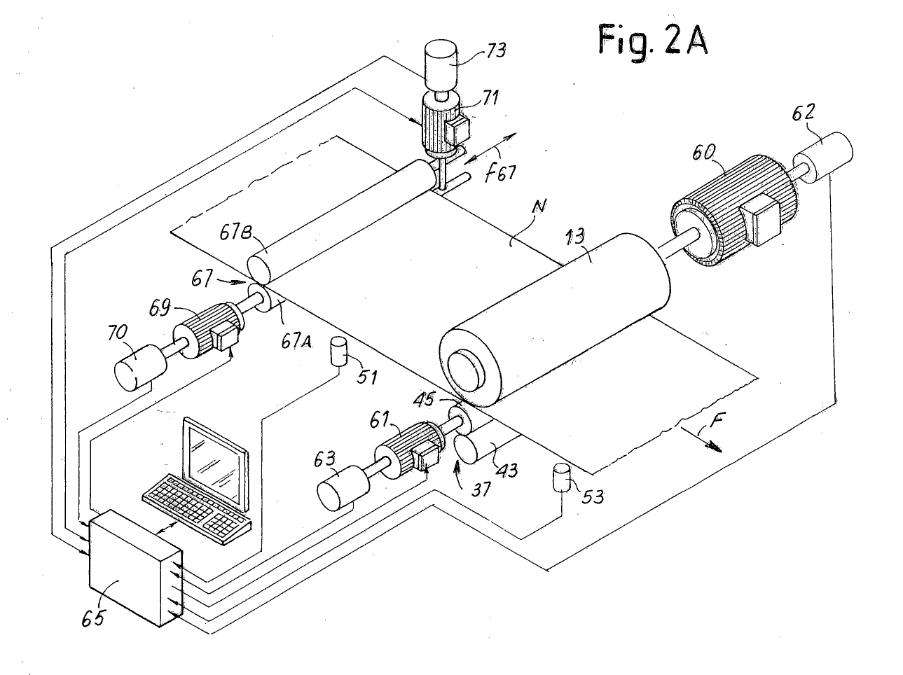

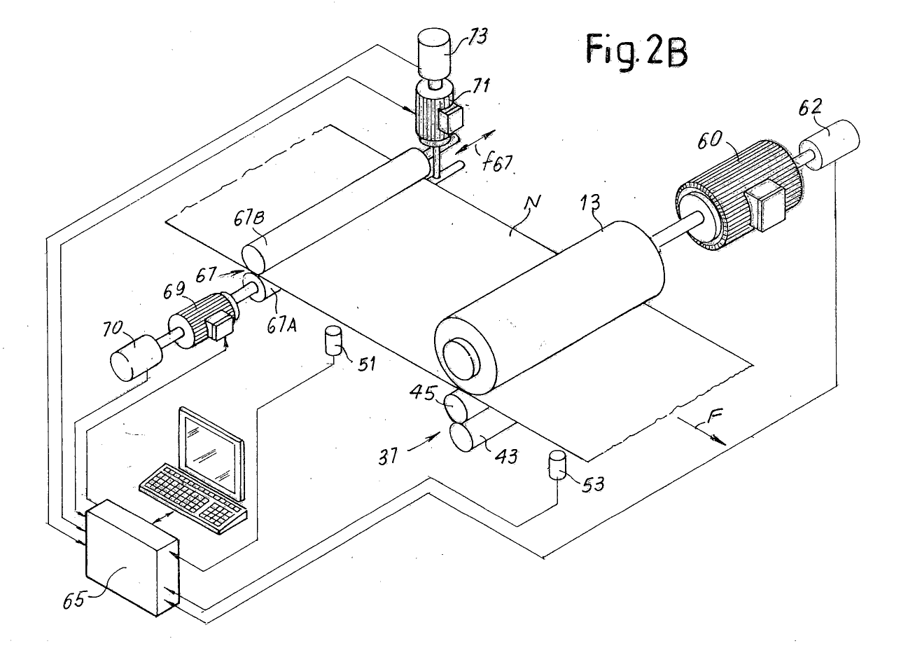

In a possible embodiment, longitudinal phasing can be obtained by controlling the angular position of the printing roller 45, which for this purpose is driven by a motor different from the main motor that drives the process roller 13. An arrangement of this type is shown in the embodiment of FIG. 2A.

In this figure, the main members of the machine are shown in a position that does not correspond to their true position, but aligned along the feed path of the web material N which has been arranged on a plane purely to simplify representation. The process roller 13 is driven in rotation by an electronically controlled electric motor 60 provided with an encoder 62. The printing roller 45, shown in a conventional manner under the process roller 13, is driven in rotation by a motor 61 with a respective encoder 63. The electronically controlled motor 61 is interfaced with an electronic control module or unit 65, to which the encoder 63 and the optoelectronic control devices 51 and 53 that read the reference marks T on the web material N are also connected.

When the encoder 63 of one or the other of the optoelectronic control devices 51, 53 detect a longitudinal phase displacement (i.e. a displacement parallel to the direction F of feed of the web material N) of the metal coating applied in the previous processing step with respect to the angular position of the printing roller 45, the motor 61 imparts a corrective movement on the printing roller 45 with micro-slipping between the printing roller 45 and the web material N to put the pattern of the printing roller 45 back into sychronism with the coating produced during the previous processing cycle.

To obtain phasing in cross direction, controllable with the same optoelectronic control devices 51, 53 and the control unit 65, action is taken on a motor-driven towing unit 67 arranged, in the example shown, between the rollers 15 and 17. In some embodiments the motor-driven towing system 67 advantageously comprises a motor-driven roller 67A and a preferably idle counter-roller 67B. The motor-driven roller 67A is driven in rotation by an electronically controlled electric motor 69 with an encoder 70. The two rollers 67A and 67B are constrained to a transversal register control motor 71, which can move both the rollers 67A and 67B crosswise, i.e. in the direction indicated with f67 transverse to the feed direction F of the web material N, pulling the web material N in this transverse movement and thereby centering it in cross direction with respect to the position of the printing roller 45. In this way, all possible cross phasing errors between the printing roller 45 and the coating deposited in the previous processing step are corrected. The motor 71 is associated with an encoder 73 and both the components 71 and 73 are connected to the electronic control unit 65 which receives information from the optoelectronic control devices 51 and/or 53. In the example shown also the motor 69 and the encoder 70 are connected to the electronic control unit 65.

FIG. 2B shows a modified embodiment of the phasing system of the web material N in the subsequent steps of deposition of the electrically conductive material. The same numbers indicate the same or equivalent parts to those of the embodiment shown in FIG. 2A. In FIG. 2B the printing roller 45 is not controlled by a motor provided with encoder, but is frictionally driven by the process roller 13 and by the anilox roller 43. These latter are driven in rotation by the main motor 60, provided with encoder 62, which drives the process roller 13. A constructional solution of this type for driving in rotation the printing roller 45 is described in WO-A-2008/116617.

In this case cross phasing is obtained in the manner described above with reference to FIG. 2A, while longitudinal phasing parallel to the direction F of feed of the web material N is obtained by acting on the previously described towing unit 67. For this purpose, the motor 69 can be accelerated or decelerated by means of the central control unit 65, so as to impart a greater or lesser tension on the web material N which causes longitudinal phasing of the printing roller 45 with respect to the pattern obtained by deposition of the electrically conductive material carried out in the previous step.

With the systems described above in one or the other of the two configurations, it is possible to carry out several vacuum deposition cycles of electrically conductive material on the same web material N, phasing the pattern of the printing roller 45 in an extremely precise manner in each single step.

The process for producing RFID antennas is therefore the following. The blank reel B of web material N is arranged inside the machine on the unwinder 5. The vacuum chamber 3 is closed and the pressure is reduced therein until obtaining a sufficient degree of vacuum in the two portions 3A, 3B of the chamber 3. Unwinding of the web material N from the reel B and gradual winding thereof on the reel B1 on the winder 7 then takes place. The web material N is entrained around the process roller 13 and, before entering the vaporization and deposition area of the electrically conductive material vaporized by the sources 33, the web is wetted by the printing unit 37 with the liquid dispensed from the tank 39 to the anilox roller 43 according to a pattern complementary to the pattern of the antennas A to be manufactured. Passing in front of the vaporization sources 33 the web material N receives the electrically conductive material vaporized by the sources, which condenses on the web material N due to cooling of the process roller 13. In the areas wetted by the liquid applied by the printing unit 37 the electrically conductive material does not adhere to the web material N, while it adheres in the dry areas, corresponding in shape to the antennas A to be produced. The liquid applied by the printing unit can evaporate before winding the web material N on the reel B1. In any case, small traces of liquid do not compromise subsequent processes (although means for removing residual traces during the process also exist).

After processing of the whole reel B has been completed, the machine is deactivated, the vacuum chamber 3 is returned to ambient pressure and the reel B1 is removed from the machine and exchanged in position, i.e. arranged once again on the unwinder 5. The cycle described above is repeated one or more times taking care to maintain the pattern formed by the previous vacuum deposition cycle in phase with the pattern of the printing roller 45, so that the layers deposited in each step according to the same pattern defined by the printing roller 45 are superimposed with high precision.

In some modified embodiments of the process according to the invention, the chamber can always be maintained in vacuum conditions, carrying out the deposition cycle several times without removing the reel from the winder and repositioning it on the unwinder. For this purpose the following steps can be carried out: the reel of material to be treated is arranged on the unwinder 5 and the web material N is fed through the chamber and around the process roller 13 to carry out deposition according to a pattern and the treated web material N is rewound on the reel B1 arranged on the winder 7. After the first passage of the web material N has been completed, preferably without the tail thereof detaching from the central winding support of the reel B, the vaporization sources 33 and preferably the printing unit 37 are deactivated, the reel is rewound on the winder, unwinding the reel B1 and once again forming the reel B. After rewinding has been carried out, a deposition cycle is once again carried out dispensing the web material N from the reel B around the process roller 13 and rewinding the material around the reel B1.

These operations can be repeated one or more times, according to the amount of electrically conductive material deposited at each passage and according to the desired thickness of electrically conductive material to be reached. After reaching the desired thickness, the machine is returned to ambient pressure, the chamber 3 is opened and the treated reel B1 is unloaded from the machine.

This cycle has the advantage of not having to restore the vacuum at each passage of the web material N. Moreover, the material being processed does not come into contact with atmospheric oxygen at each new passage, with advantages in terms of elimination or reduction of oxidation phenomena.

FIG. 5 shows an enlarged schematic section, not to scale, of a portion of the antenna A of FIG. 4. This figure schematically indicates three layers S1, S2 and S3 obtained by depositing the electrically conductive material in three subsequent processing steps as described above. In the finished product, the three layers S1, S2 and S3 will be almost perfectly superimposed, with a minimum deviation in longitudinal and/or cross direction due to impossibility of reaching perfect phasing. The degree of precision obtainable is in any case sufficient for the intended purpose of the product that is obtained.

FIG. 6 shows the use of an antenna manufactured with the process described above for producing an RFID device or tag, indicated as a whole with D and comprising a portion of web material N on which an antenna A, electrically connected to an integrated circuit I, is produced.

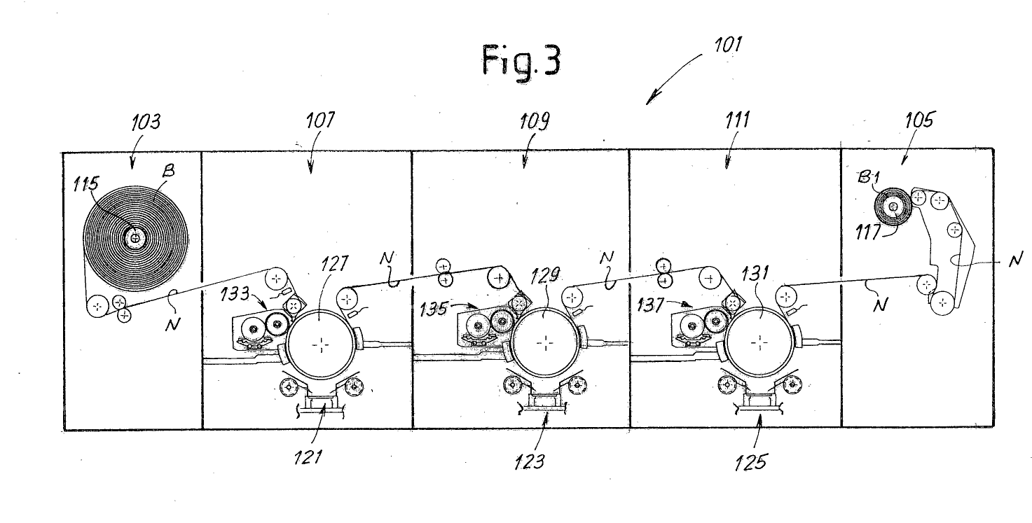

Instead of carrying out the same deposition process in a roll-to-roll machine of the type shown in FIG. 1, the process for multiple and sequential deposition of several layers S1-S3 to produce the antenna A can also be carried out with a continuous process in a multi-chamber deposition machine. FIG. 3 schematically shows a solution of this type.

In FIG. 3 the numeral 101 indicates as a whole a multi-chamber machine comprising an unwinding chamber 103, a rewinding chamber 105 and three vacuum deposition chambers 107, 109, 111. In the unwinding chamber 103 the unwinder 115 is arranged for a reel B of blank material, for example a film or other web material N. The winder 117 on which the web material N is rewound after processing is arranged in the winding chamber 105. The web material N passes through the three vacuum deposition chambers 107, 109 and 111, in each of which there is arranged a set of vaporization sources 121, 123, 125. Above the vaporization sources 121, 123, 125 there are arranged respective process rollers 127, 129, 131. With each process roller there is associated a printing unit, respectively 133, 135 and 137, designed in the same manner as the unit 37 described with reference to FIGS. 1, 2A and 2B. There are also provided analogous longitudinal and cross phasing or centering systems of the web material N for each printing unit, which, for example, are also designed as described with reference to FIGS. 1, 2A and 2B.

In substance, the multi-chamber machine 101 duplicates the arrangement of the members shown with reference to FIG. 1 for each of the deposition chambers 107, 109 and 111. In this way, with a single passage of the web material N unwound from the reel B there are deposited according to the preset pattern the same number of layers of electrically conductive material as the number of deposition chambers 107, 109, 111.

In some embodiments, along the path of the web material there can be provided at least one plasma treatment station, preferably downstream of one or of each vaporization source. The plasma station carries out a plasma-etching cleaning operation of the surface of the web material to eliminate any residue of masking liquid applied to the web material. Preferably, the plasma station uses helium, oxygen or mixtures thereof. In FIG. 1 the numeral 22 indicates by way of example a station of this type, arranged between the rollers 21 and 23. Analogously, plasma stations can also be provided in the other embodiments illustrated.

It is understood that the drawing shows just one example, provided merely as a practical demonstration of the invention, which can vary in its forms and arrangements, without however departing from the scope of the concept underlying the invention. Any reference numbers in the appended claims are provided to facilitate reading of the claims with reference to the description and to the drawing, and do not limit the scope of protection represented by the claims.

1. A method for producing RFID antennas by means of vacuum deposition of an electrically conductive material on a web material, characterized by:
a. applying on said web material, according to a pattern complementary to the pattern of the RFID antennas to be produced, a liquid which prevents anchoring of the electrically conductive material on the web material, so that the electrically conductive material dispensed by the vaporization source anchors on the web material only on the surfaces corresponding to the RFID antennas to be produced;
b. carrying out at least a first deposition of said electrically conductive material according to a pattern corresponding to the shape of the RFID antennas;
c. repeating steps (a) and (b) a number of times sufficient to reach a preset thickness of the electrically conductive material forming the RFID antennas.

2. Method according to claim 1, characterized in that at each application of said liquid subsequent to the first application, the complementary pattern according to which said liquid is applied is phased with the electrically conductive material applied in the previous phase.

3. Method according to claim 1, characterized by the steps of:
a. feeding the web material around a process roller;
b. applying said liquid to the web material according to said complementary pattern;
c. depositing the electrically conductive material on said web material according to the pattern corresponding to the RFID antennas to be produced;
d. repeating steps (a) and (b) a number of times sufficient to reach a preset thickness of the electrically conductive material forming the RFID antennas.

4. Method according to claim 1, characterized by the steps of:
feeding the web material in sequence around at least a first and a second process roller arranged in series along a feed path;
applying said liquid to the web material according to said complementary pattern;
depositing a first amount of electrically conductive material on said web material according to the pattern corresponding to the RFID antennas to be produced with a first vaporization source associated with the first process roller;
applying said liquid again to the web material according to said complementary pattern;
depositing a second amount of electrically conductive material on said web material according to the pattern corresponding to the RFID antennas to be produced with a second vaporization source associated with the second process roller.

5. Method according to claim 4, characterized by depositing further amounts of electrically conductive material on said web material according to the pattern corresponding to the RFID antennas to be produced with further vaporization sources associated with further process rollers arranged in series along the feed path.

6. Method according to claim 4, characterized by arranging a liquid applicator upstream of each process roller and applying said liquid on the web material by means of the respective applicator before deposition of the respective amount of electrically conductive material by the vaporization source associated with the respective process roller.

7. Method according to claim 1, characterized by the steps of:
a. arranging a reel of web material to be processed in a metallization system comprising at least: an unwinder, a process roller, a vaporization source associated with said process roller, and a winder;
b. unwinding said reel of web material to be processed by means of said unwinder;
c. feeding the web material, unwound from said reel of web material to be processed, along a feed path and around the process roller;
d. applying said liquid to the web material upstream of said process roller;
e. depositing, by means of said vaporization source, a first amount of electrically conductive material on the web material according to the pattern corresponding to the RFID antennas to be produced;
f. rewinding the web material on a winding reel;
g. at the end of processing of the reel of web material to be processed, arranging the winding reel on the unwinder and repeating one or more times the steps (b) to (f) depositing, according to the same pattern and in phase therewith, further amounts of electrically conductive material.

8. Method according to claim 1, characterized by the steps of:
a. arranging a reel of web material to be processed in a metallization system comprising a vacuum chamber in which there are arranged at least: an unwinder, an applicator of said liquid; a process roller, a vaporization source associated with said process roller, and a winder;
b. closing the vacuum chamber and generating a degree of vacuum in said vacuum chamber sufficient for the deposition of the electrically conductive material;
c. unwinding said reel of web material to be processed by means of said unwinder;
d. feeding the web material, unwound from said reel of web material to be processed, along a feed path and around the process roller;
e. applying said liquid to the web material upstream of said process roller;
f. by means of said vaporization source, depositing a first amount of electrically conductive material on the web material according to the pattern corresponding to the RFED antennas to be produced;
g. rewinding the web material on a winding reel;
h. returning the pressure of said deposition chamber to ambient pressure;
i. removing the reel from the winder;
j. transferring the winding reel to the unwinder;
k. repeating steps (b) to (j) one or more times, depositing further amounts of electrically conductive material according to the same pattern and in phase therewith.

9. Method according to claim 1, characterized by the steps of:
a. arranging a dispensing reel of web material to be processed in a metallization system comprising at least: an unwinder, an applicator of said liquid; a process roller, a vaporization source associated with said process roller, and a winder;
b. unwinding said reel of web material to be processed by means of said unwinder;
c. feeding the web material, unwound from said reel of web material to be processed, along a feed path and around the process roller;
d. applying said liquid to the web material upstream of said process roller;
e. by means of said vaporization source depositing a first amount of electrically conductive material on the web material according to the pattern corresponding to the RFID antennas to be produced;
f. rewinding the web material on a winding reel;
g. unwinding the web material from the winding reel and rewinding it on a reel on the unwinder;
h. repeating steps (b) to (g) until reaching a desired thickness of the electrically conductive material forming the RFID antennas.

10. Method according claim 1, characterized by removing residues of said liquid from the web material after each deposition of the electrically conductive material.

11. Method according to claim 10, characterized in that said residues are removed by a plasma process.

12. Method according to claim 11, characterized in that said plasma process is carried out using helium, oxygen or mixtures thereof.

13. Method according to claim 1, characterized in that said web material is fed continuously.

14. Method according to claim 13, characterized in that said web material is fed at a speed between 50 and 1000 m/min.

15. A system for vacuum deposition of a conductive material on a web material, for producing RPID antennas, comprising: at least one vacuum chamber; at least one unwinder for a reel of web material; at least one winder for winding the processed web material; at least one feed path of the web material from the unwinder to the winder; at least one vaporization source; at least one applicator of a liquid on the web material upstream of said vaporization source, for preventing anchoring of the electrically conductive material at a pattern complementary to a pattern of the RFID antennas to be manufactured; a system for phasing the applicator with respect to the web material.

16. System according to claim 15, comprising at least one process roller along said feed path of the web material, said vaporization source being associated with said process roller.

17. System according to claim 15, wherein the phasing system of the applicator comprises: at least one detector for detecting a reference on the web material; longitudinal phasing members and cross phasing members of the web material controlled by signals from said detector.

18. System according to claim 17, wherein said cross phasing members comprise at least one motor-driven roller, around which the web material is fed, provided with a controlled movement in axial direction, the cross phasing being controlled through an axial movement of said at least one motor-driven roller.

19. System according to claim 18, wherein said at least one motor-driven roller is arranged upstream of the process roller.

20. System according to claim 18, wherein said at least one motor-driven roller is associated with a pressure roller and forms a towing unit of said unwinder, for unwinding the web material from a reel.

21. System according to claim 18, wherein said longitudinal phasing members comprise a device for varying the tension of the web material by acting on the speed of said motor-driven roller.

22. System according to claim 17, wherein said longitudinal phasing members comprise a device for varying the rotation speed of a printing roller of the liquid applicator unit with respect to the web material.

23. System according to claim 17, comprising two detectors for detecting said references on the web material, arranged upstream and downstream of the process roller respectively.

24. System according to claim 15, comprising a plurality of process rollers arranged in series along a feed path of the web material between said unwinder and said winder; and wherein each process roller is associated with: a vaporization source; at least one respective applicator of a liquid on the web material upstream of said vaporization source, for preventing anchoring of the electrically conductive material at a pattern complementary to a pattern of the RFID antennas to be produced; a respective phasing system of the applicator with respect to the web material.

25. System according to claim 15, comprising, for each process roller, a plasma treatment station for removing residues of said liquid from the web material.

26. A web material comprising a plurality of coatings of electrically conductive, vacuum-deposited material defining RFID antennas, each coating consisting of the superimposition of several layers deposited in sequence.

27. An RFID antenna comprising a sheet support whereon there is provided a coating of electrically conductive material consisting of several superposed layers deposited in sequence.

28. An electronic device comprising a sheet support whereon there is applied at least one integrated circuit in electrical connection with an RFID antenna consisting of at least one coating of electrically conductive material consisting of several superposed layers deposited in sequence.
